(19) United States
(12) Patent Application Publication
(10) Pub. No.: US 2008/0265889 A1
(43) Pub. Date: Oct. 30, 2008

(54) Multiple-Channel Transmit Magnetic Resonance

(75) Inventors: Zhiyong Zhai, Cleveland, OH (US); Michael A. Morich, Mentor, OH (US); Gordon D. DeMeester, Wickliffe, OH (US)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N. V., Eindhoven (NL)

(21) Appl. No.: 12/089,057

(22) PCT Filed: Sep. 14, 2006
(86) PCT No.: PCT/IB06/53294

§ 371 Date: Apr. 3, 2008

Related U.S. Application Data
(60) Provisional application No. 60/725,051, filed on Oct. 7, 2005.

(51) Int. Cl. G01R 33/3415

(52) U.S. Cl. 324/318

(57) ABSTRACT

In a transmit apparatus, a multi-channel radio frequency transmitter (30, 46) includes a plurality of transmit elements (32) defining at least two independently operable transmit channels. A transmit configuration selector (54) determines a selected transmit configuration (60) specifying amplitude and phase applied to each transmit channel to generate a B₁ field in a corresponding selected region (90) of a subject (38) coupled with the radio frequency transmitter. The transmit configuration selector determines the selected transmit configuration based on B₁ mapping (58) of the subject and a B₁ field quality assessment employing at least two different B₁ field quality measures.

The following relates to the magnetic resonance arts. It finds particular application in conjunction with magnetic resonance imaging employing a transverse electromagnetic (TEM) coil in which the rods, or selected groups of rods, are independently operable as transmit channels, and will be described with particular reference thereto. It finds application more generally in conjunction with radio frequency (RF) transmitters for generating magnetic resonance that include a plurality of transmit elements (such as the aforementioned TEM coil rods, or degenerate birdcage coil meshes, or surface transmit coils, or so forth) defining at least two independently operable transmit channels for use in magnetic resonance spectroscopy, magnetic resonance imaging, and so forth.

Magnetic resonance imaging, magnetic resonance spectroscopy, and so forth are typically performed in a static magnetic field of between about 0.5 Tesla and about 7 Tesla, with higher static magnetic fields contemplated. For ¹H proton imaging, the magnetic resonance frequency is about (42.56 MHz/Tesla)×|B₀|, where |B₀| is the magnitude of the static magnetic field. Thus, for example, the ¹H proton frequency is about 64 MHz at 1.5 Tesla, about 128 MHz at 3.0 Tesla, and about 298 MHz at 7.0 Tesla. The magnetic resonance wavelength in the subject is given by the speed of light in free space divided by the magnetic resonance frequency divided by the square root of the dielectric constant. For higher magnetic resonance frequencies and subjects with relatively large dielectric constant (such as human beings), the wavelength becomes comparable to the dimensions of the subject.

Transmit coils are typically designed to produce a substantially uniform B₁ field in the unloaded state. At lower magnetic resonance frequencies, the effect of loading on B₁ field uniformity is typically limited. As the wavelength at the magnetic resonance frequency approaches the size of the subject, the B₁ field can become more non-uniform. Typically, B₁ field non-uniformity due to the subject is apparent for human body imaging at 3 Tesla and apparent in head imaging at 7 Tesla. In the case of head imaging at 7 Tesla, for example, the flip angle can vary by a factor of two or more within a slice when using a radio frequency transmit coil that produces a substantially uniform B₁ field in the unloaded condition.

One proposed approach for addressing loading-induced B₁ non-uniformity is to employ an array of independently driven transmit channels, such as independently driven rods or groups of rods of a TEM coil. In such an approach, each transmit channel is driven by radio frequency power having an independent amplitude and phase, with the amplitudes and phases of the channels selected such that the channels cooperatively combine to produce a substantially uniform B₁ field in the subject.

While this approach can provide improved B₁ field uniformity for a loaded coil, practical difficulties are encountered. For “N” transmit channels each having “A” selectable amplitudes (for example, “A” steps spanning an achievable range of radio frequency power amplitudes for the transmit element) and having “P” selectable phases (for example, “P” steps spanning a phase range 0°-360°), the total number of possible transmit configurations for the N transmit elements is (A×P)^{N}. For example, for eight transmit channels each having A=10 amplitude settings and P=36 phase settings, the number of possible transmit configurations is (10×36)⁸, that is, about 2.8×10²⁰ possible transmit configurations. Selecting a suitable transmit configuration from amongst this enormous number of possible configurations is computationally intense. Evaluation of each considered transmit configuration involves computing the B₁ field and assessing the desirability of the computed B₁ field. These computationally intensive operations are performed for each considered transmit configuration. Even using a high speed supercomputer, an exhaustive search of 10²⁰ such combinations during an imaging session is impractical.

The following contemplates improvements that overcome the aforementioned limitations and others.

According to one aspect, a transmit apparatus is disclosed for exciting magnetic resonance. A multi-channel radio frequency transmitter includes a plurality of transmit elements defining at least two independently operable transmit channels. A transmit configuration selector determines a selected transmit configuration specifying amplitude and phase applied to each transmit channel to generate a B₁ field in a corresponding selected region of a subject coupled with the radio frequency transmitter. The transmit configuration selector determines the selected transmit configuration based on B₁ mapping of the subject and a B₁ field quality assessment employing at least two different B₁ field quality measures.

According to another aspect, a magnetic resonance system is disclosed. A transmit apparatus is provided as set forth in the immediately preceding paragraph. A main magnet is provided for generating a static magnetic field at least in the selected region of the subject coupled with the radio frequency transmitter. Magnetic field gradient coils are provided for superimposing selected magnetic field gradients on the static magnetic field at least in the selected region of the subject coupled with the radio frequency transmitter.

According to another aspect, a transmit configuration selector is disclosed for determining a selected transmit configuration to be applied by an associated multi-channel radio frequency transmitter to produce a B₁ field in a corresponding selected region. The associated multi-channel radio frequency transmitter includes a plurality of transmit elements defining at least two transmit channels. The transmit configuration selector comprises: means for determining a B₁ field map of at least the selected region for a transmit configuration under consideration; means for assessing the B₁ field based on at least two different quality measures; and means for applying the B₁ mapping means and assessing means for different transmit configurations under consideration to determine the selected transmit configuration.

According to another aspect, a method is disclosed for determining a selected transmit configuration to be applied by a multi-channel radio frequency transmitter to produce a B₁ field in a corresponding selected region. The multi-channel radio frequency transmitter includes a plurality of transmit elements defining at least two transmit channels. A B₁ field is determined in at least the selected region for a transmit configuration under consideration. The determined B₁ field is assessed based on at least two different quality measures. The determining and assessing are repeated for different transmit configurations under consideration to determine the selected transmit configuration.

One advantage resides in improved B₁ field uniformity within a slice or other excited region.

Another advantage resides in improved B₁ field uniformity across slices or across other excited regions.

Another advantage resides in reduced maximum SAR.

Another advantage resides in more uniform B₁ field range within a slice or other excited region.

Another advantage resides in more uniform B₁ field range across slices or across other excited regions.

Another advantage resides in improved image quality.

Numerous additional advantages and benefits will become apparent to those of ordinary skill in the art upon reading the following detailed description of the preferred embodiments.

The invention may take form in various components and arrangements of components, and in various process operations and arrangements of process operations. The drawings are only for the purpose of illustrating preferred embodiments and are not to be construed as limiting the invention.

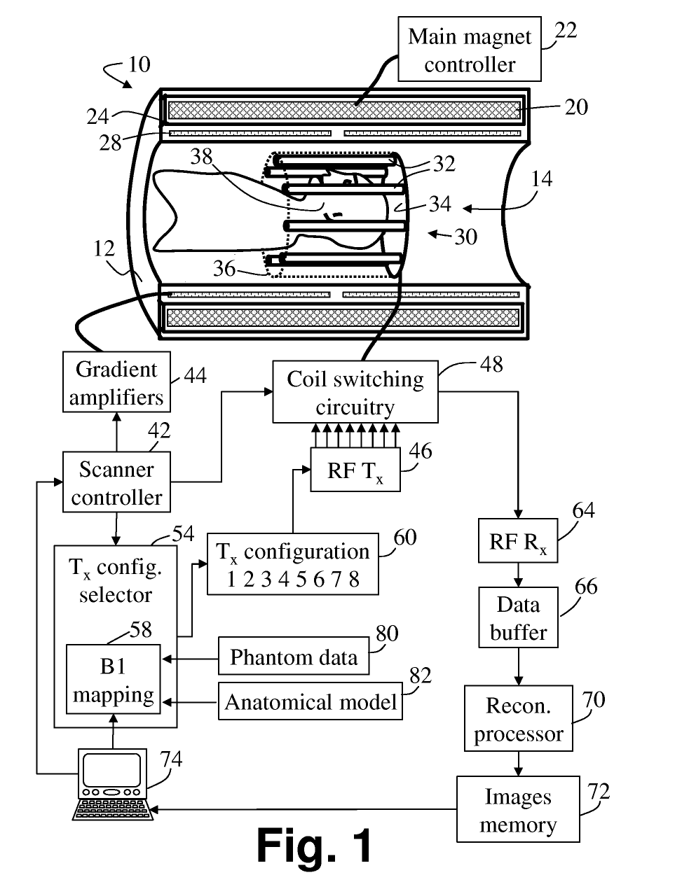

FIG. 1 diagrammatically shows an example magnetic resonance system employing an eight-rod transmit/receive (T/R) TEM coil as an eight-channel transmitter and as a volumetric receiver. The magnetic resonance scanner is shown in perspective sectional view to reveal selected internal components.

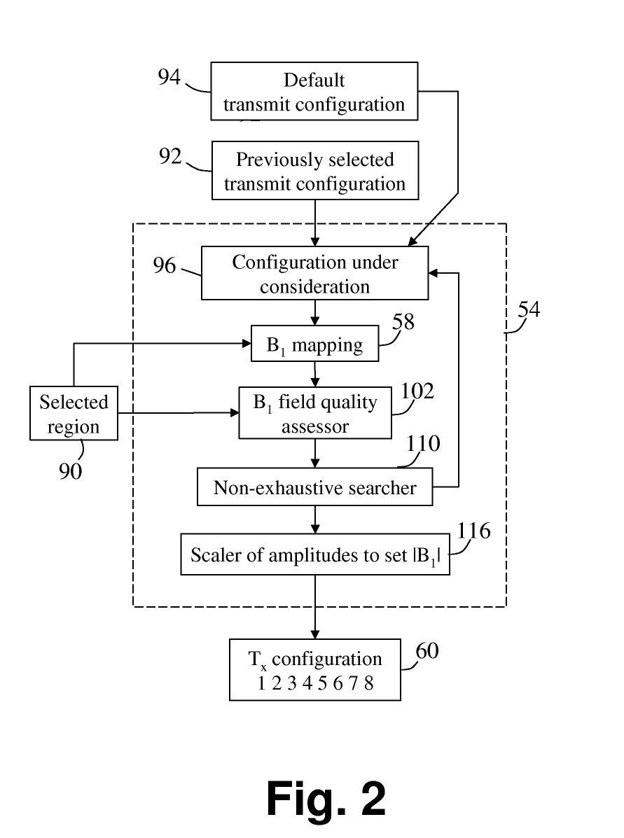

FIG. 2 diagrammatically shows an example embodiment of the transmit configuration selector.

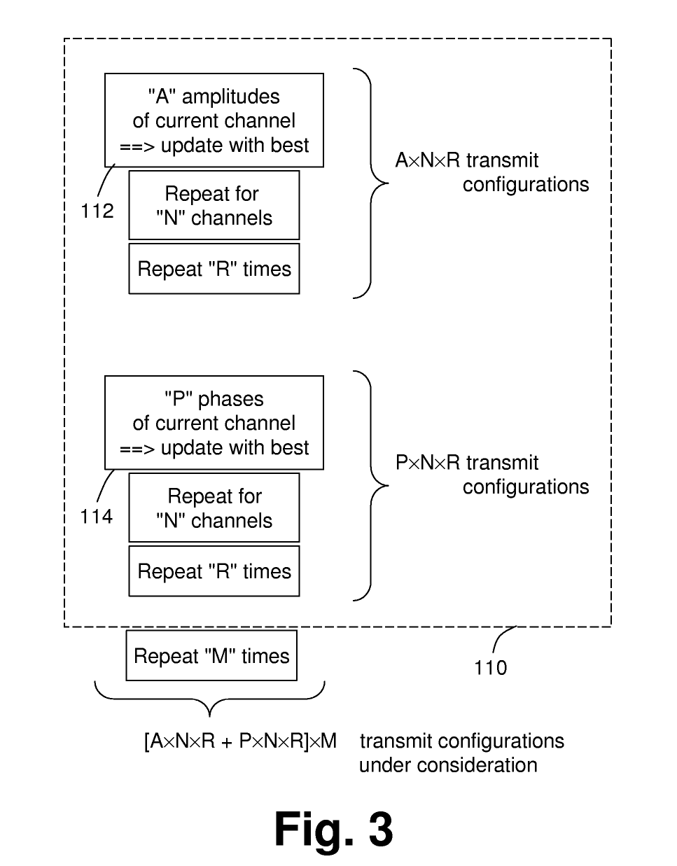

FIG. 3 diagrammatically shows an example embodiment of the non-exhaustive searcher.

With reference to FIG. 1, a magnetic resonance scanner 10 includes a scanner housing 12 including a bore 14 or other receiving region for receiving a patient or other subject. A main magnet 20 disposed in the scanner housing 12 is controlled by a main magnet controller 22 to generate a main B₀ magnetic field in an examination region within the bore 14. Typically, the main magnet 20 is a persistent superconducting magnet surrounded by cryoshrouding 24, although a resistive or permanent main magnet can be used for lower B₀ field strengths.

Magnetic field gradient coils 28 are arranged in or on the housing 12 to superimpose selected magnetic field gradients on the main magnetic field at least in the examination region. Typically, the magnetic field gradient coils include coils for producing three orthogonal magnetic field gradients, such as an x-gradient, y-gradient, and z-gradient. A TEM transmit/receive (T/R) radio frequency coil 30 is used to inject B₁ radio frequency excitation pulses and to receive magnetic resonance signals. The example coil 30 is a TEM coil including, for example, eight rods 32, an optional end cap 34, and a surrounding radio frequency shield or screen 36 (shown in phantom). The radio frequency coil 30 is disposed about a human head 38 which is the subject of interest.

A scanner controller 42 operates gradient amplifiers 44, a multi-channel radio frequency amplifier 46, and associated coil switching circuitry 48 to excite, spatially localize, encode, or otherwise manipulate magnetic resonance in the head subject 38. During the transmit phase, the radio frequency amplifier 46 independently drives the amplitude and phase of radio frequency power delivered to each rod of the eight-rod TEM coil 30 to operate the TEM coil 30 as an eight-channel transmitter array. In other embodiments, the eight-rod TEM coil 30 coil may be operated as a four-channel transmitter array employing four interleaved rods for four transmit channels, or employing two rods as one transmit group per transmit channel. In other embodiments, the TEM coil may include a number of rods other than eight, such as ten rods, twelve rods, sixteen rods, or so forth, which are driven as a four-channel transmitter, five-channel transmitter, eight-channel transmitter, ten-channel transmitter, sixteen-channel transmitter, or so forth. In other embodiments, other transmitter arrays may be used, such as a degenerate birdcage coil with decoupled meshes defining a plurality of transmit channels, or an array of surface transmit coils defining a plurality of independent transmit channels, or so forth.

Each transmit channel is independently operated at a selected amplitude and phase of input radio frequency power. A transmit configuration selector 54 selects the amplitude and phase for each transmit channel for exciting magnetic resonance in a selected region based on B₁ mapping 58 of the head 38 or other subject. The amplitude and phase selected for each transmit channel collectively defines a selected transmit configuration 60 that when applied to the eight rods 32 produces a B₁ field that is substantially uniform or has another selected spatial distribution over the corresponding selected region of the head 38 or other subject.

During the receive phase of the magnetic resonance sequence, the coil switching circuitry 48 connects the TEM head coil 30 as a volume resonator to a radio frequency receiver 64 to receive excited and spatially encoded magnetic resonance signals. Depending upon the type of magnetic resonance sequence being implemented, the magnetic field gradient coils 28 may operate during at least a portion of the receive phase, for example to provide frequency encoding or spoiling of the magnetic resonance. A data buffer 66 stores the received magnetic resonance signals, typically after they are digitized and have optionally undergone other signal processing. In some embodiments, a separate receive-only coil (not shown) is used during the receive phase of the magnetic resonance sequence, rather than using the same coil 30 for both transmit and receive phases.

For imaging, a reconstruction processor 70 performs reconstruction processing on the collected magnetic resonance data to generate a reconstructed image or map therefrom. For example, the reconstruction processor 70 may process spatially encoded magnetic resonance data using a Fast Fourier Transform (FFT) or other reconstruction algorithm to generate a spatial map or image of the subject. For spectroscopy or other magnetic resonance applications, other types of post-processing may be employed in conjunction with or in place of spatial image or map reconstruction.

An images memory 72 stores the reconstructed image or map. A user interface 74 displays the reconstructed image or map to an associated user. In the example embodiment illustrated in FIG. 1, the user interface 74 also interfaces the user with the scanner controller 42 to control the magnetic resonance scanner 10. In other embodiments, a separate scanner control interface may be provided. In some embodiments, the user interface 74 may be a computer or other digital electronics. Optionally, the reconstruction processor 70, memories 66, 72, and/or other components are integrated with such computer or digital electronics as software components, hardware add-ons, or so forth.

In some embodiments, a portion or all of the coil switching circuitry 48 is located on the TEM coil 30 or other radio frequency coil. In some embodiments, the coil switching circuitry 48 can selectively configure the radio frequency coil as a single volumetric receive coil, or as an array of receive coils. For example, each rod, or selected group of rods, of the TEM coil 30 can optionally be used as a SENSE receive element in the receive phase of the magnetic resonance sequence. In some embodiments, the coil 30 is operated as both an eight-channel transmitter and as an eight-channel receive array with suitable switching circuitry. In some embodiments, separate transmit and receive coils or coil arrays are provided.

The B₁ mapping 58 can be determined in various ways. In one approach, the B₁ mapping 58 is determined from B₁ mapping measurements of the subject acquired using the TEM coil 30 and the magnetic resonance scanner 10. Alternatively, the B₁ mapping 58 can be determined from phantom magnetic resonance data 80 acquired for a phantom representative of the subject, or from a model of the subject, such as an anatomical model 82 of the head 38. Suitable anatomical models for various portions of human anatomy, as well as for anatomies of the Sprague-Dawley rat, pigmy goat, and rhesus monkey, are available from the United States Air Force Research Laboratory (http://www.brooks.af.mil/AFRL/HED/hedr, last visited Aug. 30, 2005).

The inventors have found that a transmit configuration that provides a substantially uniform B₁ field over one selected region of the head 38 may provide a highly non-uniform B₁ field over another selected region. For example, a transmit configuration that provides a substantially uniform B₁ field for an axial slice near the crown of the head 38 may provide a highly non-uniform B₁ field for a more centrally-located axial slice. Accordingly, the transmit configuration selector 54 repeats the determination of the selected transmit configuration 60 for a plurality of slices, for a plurality of groups of adjacent slices, or for various other selected regions. In some embodiments, the selected regions correspond to acquisition regions. For example, the selected transmit configuration 60 may be re-determined for each acquired axial slice. In other embodiments, each selected region corresponds to a plurality of contiguous acquisition regions. For example, the selected transmit configuration 60 may be re-determined for a crown group of slices, for one, two, or more intermediate contiguous groups of slices, and for a group of slices near the neck region.

With reference to FIG. 2, a suitable embodiment of the transmit configuration selector 54 is described. The transmit configuration selector 54 receives as inputs the B₁ mapping 58 and a selected region 90, provided for example by the scanner controller 42. Optionally, the transmit configuration selector 54 further receives the previously selected transmit configuration 92 (if one is available), which is used as a starting transmit configuration for consideration. Alternatively (or if a previously selected transmit configuration is unavailable), a default transmit configuration 94 can be used as the starting transmit configuration for consideration. For example, the default transmit configuration can be a transmit configuration known to provide a substantially uniform B₁ field for the selected region 90 of a typical head, or can be a transmit configuration known to provide a substantially uniform B₁ field when the TEM coil 30 is not loaded.

A transmit configuration under consideration 96 is initially the previously selected transmit configuration 92, the default transmit configuration 94, or so forth. The B₁ field mapping 58 determines the B₁ field as a function of position for the transmit configuration under consideration at least within the selected region 90. The B₁ mapping 58 can employ direct measurement of the B₁ field using the radio frequency coil 30 and the magnetic resonance scanner 10, or can estimate the B₁ field by modeling or calculation. For modeling or calculation of the B₁ field, the phantom data 80 or anatomical model 82 (see FIG. 1) are used, along with a model of the radio frequency coil 30. The B₁ mapping 58 can be isotropic or anisotropic, and can be the same as the imaging resolution, or, to speed the computation of the B₁ field, coarser than the imaging resolution. A coarse resolution is suitable for modeling the B₁ field since the B₁ field non-uniformity pattern is expected to exhibit predominantly low spatial frequencies.

In some embodiments, the B₁ field mapping 58 employs XFDTD full wave 3D electromagnetic solver software (available from Remcom, State College, Pa.). The generated electromagnetic fields by each rod 32 acting alone are calculated in accordance with the amplitude and phase for that rod given by the transmit configuration under consideration, and the combined electromagnetic fields generated by all of the rods 32 acting together is determined by superposition of the B₁ radio frequency fields in the subject 38 produced by each rod 32 acting alone. The B₁⁺ magnetic resonance excitation field is calculated for all cells or pixels at least in the selected region 90. The described FDTD approach is an example—other techniques can be used for computing or modeling the B₁ field.

A B₁ field quality assessor 102 assesses the quality of the B₁ field calculated for the transmit configuration under consideration. Various measures can be used for assessing B₁ field quality. A range measure, denoted herein as “r”, is suitably given by:

$$r = \frac{{\vert {B}_{1}^{+} \vert}_{max}}{{\vert {B}_{1}^{+} \vert}_{min}} , \qquad ( 1 )$$

where the range “r” is determined respective to the selected region 90. The term range and corresponding symbol “r” is intended to encompass obvious variants of Equation (1), such as including linear scaling or normalization, inverting the ratio, and so forth. A statistical deviation measure, denoted herein as “s”, is suitably given by a variance, standard deviation, root-mean-square (rms) value, or so forth, applied over the selected region 90. A specific absorption rate (SAR) measure can also be used, such as a local SAR value (maximum SAR over a local volume unit such as an average over a 10 gram local volume unit) or a head SAR (maximum average SAR in the head 38).

The inventors have found that assessing the B₁ field quality based on a single measure, such as based only on range “r”, or only on statistical deviation “s”, or only on local SAR, or only on head SAR, typically does not yield a satisfactory selected transmit configuration. For example, selecting the transmit configuration by minimizing the statistical deviation “s” alone may yield a mostly uniform B₁ field across the selected region 90 that includes one or more places where |B₁| deviates substantially from the average |B₁|_{avg} value, leading to an undesirably large range “r” value and a high local SAR. Similarly, selecting the transmit configuration to provide range “r” closest to unity, without considering other quality measures, may produce a B₁ field that has no spatial locations where the B₁ field becomes very large or very small. However, the selected B₁ field may exhibit an undesirably large statistical deviation due to a substantial amount of smaller-amplitude B₁ field variation, or the power requirement may be relatively high, or so forth.

Accordingly, the B₁ field quality assessor 102 assesses the quality of the B₁ field calculated for the transmit configuration under consideration using at least two different quality measures. In one embodiment, the assessor 102 employs the range “r” measure and the statistical deviation “s” measure together for the assessment, for example assessing B₁ field quality by minimizing the statistical deviation “s” while having a range “r” less than a threshold value:

s→0⁺ AND r<r₀ where r₀=threshold value (2).

Other assessments can be used. For example, in the assessment of Equation (2), a threshold on the local or head SAR may be substituted for the range threshold criterion, yielding the assessment:

s→0⁺ AND SAR<SAR₀ where SAR₀=threshold value (3),

where SAR may refer to local SAR, head SAR, or the maximum or average specific absorption rate over another selected volume.

A non-exhaustive searcher 110 applies the B₁ field mapping 58 and assessor 102 for different transmit configurations under consideration to determine the selected transmit configuration 60. The searching is non-exhaustive. As discussed in the Background, for “N” transmit elements each having “A” amplitude steps or settings spanning an achievable range of radio frequency power amplitudes and “P” phase steps or settings spanning a phase range 0°-360°, the total number of possible transmit configurations for the N transmit elements is (A×P)^{N}. For the example case in which N=8, A=10, and P=36, the number of possible transmit configurations is about 2.8×10²⁰. As the image size for calculating “r”, “s”, “SAR”, or other assessors is relatively large (for example, in some embodiments the image size is 100×100×(number of slices)), the number of possible transmit configurations represents an impractical exhaustive search.

The non-exhaustive searcher 110 does not perform an exhaustive search. Rather, the non-exhaustive searcher 110 searches a sub-set of the possible transmit configurations, and for each such transmit configuration under consideration 96 the B₁ field mapping 58 and assessor 102 are applied.

FIG. 3 shows one possible non-exhaustive search suitably performed by the non-exhaustive searcher 110. A single-channel amplitude search 112 is performed for a current transmit channel, without varying the amplitudes or phases of the other channels. The “A” amplitude steps are considered for the current channel, and the amplitude of the current channel is updated with the considered amplitude setting or step assessed by the assessor 102 as producing the best or highest quality B₁ field. The single-channel amplitude search/update 112 is repeated for each of the “N” channels to update the amplitude of each channel. The process is repeated “R” times, so that A×N×R configurations are considered.

Similarly, a single-channel phase search 114 is performed for a current transmit channel, without varying the amplitudes or phases of the other channels. The “P” phase steps are considered for the current channel, and the phase of the current channel is updated with the considered phase setting or step assessed by the assessor 102 as producing the best or highest quality B₁ field. The single-channel phase search/update 114 is repeated for each of the “N” channels to update the phase of each channel. The process is repeated “R” times, so that P×N×R configurations are considered.

The amplitude search/update and phase search/update are repeated “M” times, yielding a total of (A×N×R+P×N×R)×M transmit configurations under consideration, or in simplified form (A+P)×N×R×M transmit configurations under consideration. For the example situation of N=8, A=10, and P=36, and employing R=50 and M=25, the total number of transmit configurations under consideration is 460,000.

It will be appreciated that, because the single-channel searches 112, 114 update the amplitude and phase, respectively, of the current channel, the subsequently considered transmit configurations are based on previously considered transmit configurations. The inventors have found that for a four-channel transmitter (where an exhaustive search is feasible although computationally intensive), a non-exhaustive search in accordance with the approach of FIG. 3 rapidly determines a selected transmit configuration that is about as good as the best transmit configuration identified by performing an exhaustive search of all (10×36)⁴=1.6×10° possible transmit configurations.

The number of transmit configurations under consideration can generally be reduced by employing a priori knowledge to ensure that the initial configuration under consideration is close to satisfactory. For example, using the previously selected transmit configuration 92, obtained from the selection for an adjacent slice which has already been imaged, generally provides a close starting point for the searching. In such a case, the repetition factors “R” and “M” may be reduced.

Once the non-exhaustive searcher 110 finds a transmit configuration assessed by the assessor 102 as suitable for selection, a scaler 116 optionally proportionately scales the amplitudes of the channels of the transmit configuration to set the average |B₁| field to a target value |B₁|_{T}. A suitable scaling factor A_{S} is given by:

$${A}_{S} = \frac{{\vert {B}_{1} \vert}_{T}}{{\vert {B}_{1} \vert}_{avg}} , \qquad ( 4 )$$

where |B₁|_{avg} is the average value of the B₁ field computed by the B₁ field mapping 58. The amplitude of each transmit channel of the transmit configuration assessed as suitable for selection is multiplied by the scaling factor A_{S} to scale the average |B₁| field to the target value |B₁|_{T}, thus producing the selected transmit configuration 60.

Other search/update algorithms can be used besides the illustrated example of FIG. 3. For example, in another contemplated approach, the searcher/updater 110 randomly modifies an amplitude or phase of a randomly selected channel. For example, the randomly selected channel can have either its amplitude or its phase randomly incremented or decremented by one step. If the random modification improves the B₁ field quality as assessed by the B₁ field quality assessor 102, then the random modification is retained; otherwise it is discarded. Again, in this approach subsequent transmit configurations under consideration are derived from previous transmit configurations under consideration, so that the search is not random but rather is driven by the assessor 102 toward transmit configurations that better satisfy the assessment criterion employed by the B₁ field quality assessor 102.

In another contemplated approach, the non-exhaustive searcher 110 implements a genetic algorithm operating on a population of chromosomes each representing a transmit configuration under consideration. The chromosome genes correspond to the amplitude and phase of each channel—each chromosome includes at least 2×N genes. For the example eight-channel transmitter, a sixteen-gene chromosome is suitable. The B₁ field quality assessor 102 defines chromosome fitness for deciding which chromosomes of the population propagate into future generations. Offspring chromosomes are suitably mutated by random or pseudorandom changes in the gene values to generate new transmit configurations for consideration, and optionally employs a crossover operator or algorithm to combine parent chromosomes of the present generation population using suitable operations such as gene copying, gene mixing or swapping, gene mutation, and so forth to produce the offspring chromosomes. In some contemplated genetic algorithm-based approaches, soft restarts or other techniques for expanding the scope of the chromosome population are employed to reduce a likelihood of premature convergence.

Regardless of the particular search/update algorithm employed, the assessment employed by the assessor 102 should be chosen to provide a substantially uniform B₁ field or other desired B₁ field distribution. However, the assessment should not be chosen to be so aggressive that none of the sub-set of transmit configurations under consideration are likely to be assessed as satisfactory. For example, using the assessment of Equation (2) with r₀ close to unity may be unrealistic, since it is possible that none of the transmit configurations under consideration will satisfy this aggressive assessment. On the other hand, the inventors have found that setting r₀=2.5 provides a reasonably uniform B₁ field while being readily satisfied by the limited number of transmit configurations under consideration by the non-exhaustive searcher 110.

The inventors have performed transmit configuration selections as disclosed herein for head imaging using axial slices as the selected regions and employing an end-capped head coil transmitter having four transmit channels, eight transmit channels, or sixteen transmit channels. It was found that substantial improvement in B₁ field uniformity was obtained when the number of channels was increased from four to eight; however, further increase to sixteen channels provided less improvement while implicating substantially longer search time.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

1. A transmit apparatus for exciting magnetic resonance, the transmit apparatus comprising:
a multi-channel radio frequency transmitter including a plurality of transmit elements defining at least two independently operable transmit channels; and
a transmit configuration selector for determining a selected transmit configuration specifying amplitude and phase applied to each transmit channel to generate a B₁ field in a corresponding selected region of a subject coupled with the radio frequency transmitter, the transmit configuration selector determining the selected transmit configuration based on B₁ mapping of the subject and a B₁ field quality assessment employing at least two different B₁ field quality measures.

2. The radio frequency coil as set forth in claim 1, wherein the at least two different quality measures include at least (i) a range measure indicative of a ratio of a largest B₁ field to a smallest B₁ field in the selected region and (ii) a statistical deviation measure of the B₁ field in the selected region.

3. The radio frequency coil as set forth in claim 2, wherein the transmit configuration selector minimizes the statistical deviation while keeping the range less than a threshold value.

4. The radio frequency coil as set forth in claim 1, wherein the at least two different quality measures include at least one of (i) a local SAR measure and (ii) an average SAR measure averaged over at least the selected region.

5. The radio frequency coil as set forth in claim 1, wherein the radio frequency transmitter includes a TEM coil, the transmit elements being rods of the TEM coil, each transmit channel including at least one rod.

6. The radio frequency coil as set forth in claim 5, wherein each transmit channel includes exactly one rod.

7. The radio frequency coil as set forth in claim 1, wherein the radio frequency transmitter includes a plurality of coil array elements defined by one of (i) rods of a TEM coil, (ii) decoupled meshes of a degenerate birdcage coil, or (iii) surface transmit coils of an array of surface transmit coils, and wherein each transmit channel includes at least one coil array element.

8. The radio frequency coil as set forth in claim 7, wherein each transmit channel includes exactly one coil array element.

9. The transmit apparatus as set forth in claim 1, wherein the transmit configuration selector includes:
a B₁ field quality assessor that assesses desirability of the B₁ mapping based on the at least two different quality measures; and
a searcher that applies the B₁ field mapping and assessor for different transmit configurations under consideration to determine the selected transmit configuration.

10. The transmit apparatus as set forth in claim 9, wherein the searcher performs a method including:
performing a single-channel search of at least one of amplitude and phase of a current transmit channel without varying amplitude or phase of the other transmit channels;
updating the current transmit channel based on the single-channel search; and
repeating the single-channel search and updating for each of the at least two independently operable transmit channels.

11. The transmit apparatus as set forth in claim 9, wherein the searcher constructs each transmit configuration under consideration from a previously assessed transmit configuration under consideration by changing at least one amplitude or phase of the previously assessed transmit configuration.

12. The transmit apparatus as set forth in claim 9, wherein the searcher initiates using a previously selected transmit configuration that was previously selected for a region neighboring the selected region.

13. The transmit apparatus as set forth in claim 9, wherein the searcher implements a genetic algorithm operating on an evolving population of chromosomes in which each chromosome represents a transmit configuration under consideration.

14. The transmit apparatus as set forth in claim 1, wherein the B₁ mapping is determined from processing B₁ field mapping magnetic resonance measurements acquired of the subject.

15. The transmit apparatus as set forth in claim 1, wherein the B₁ mapping is determined from one of (i) phantom magnetic resonance data acquired from a phantom representative of the subject, and (ii) a model of the subject.

16. A magnetic resonance system comprising:
a transmit apparatus as set forth in claim 1;
a main magnet for generating a static magnetic field at least in the selected region of the subject coupled with the radio frequency transmitter; and
magnetic field gradient coils for superimposing selected magnetic field gradients on the static magnetic field at least in the selected region of the subject coupled with the radio frequency transmitter.

17. The magnetic resonance system as set forth in claim 16, further including:
coil switching circuitry that switches the radio frequency transmitter between (i) a transmit configuration in which the plurality of transmit elements define the at least two independently operable transmit channels, and (ii) a receive configuration in which the plurality of transmit elements define one of a volume resonator and an array of receive channels.

18. The magnetic resonance system as set forth in claim 16, further including:
a scanner controller that performs a magnetic resonance scan of the subject coupled with the radio frequency transmitter by acquiring magnetic resonance data for a plurality of contiguous acquisition regions spanning at least two different selected regions of the subject, the transmit configuration selector re-determining the selected transmit configuration for each different selected region of the subject.

19. The magnetic resonance system as set forth in claim 18, wherein the selected regions are identical with the acquisition regions.

20. The magnetic resonance system as set forth in claim 18, wherein each selected region contains a contiguous two or more of the plurality of contiguous acquisition regions.

21. A transmit configuration selector for determining a selected transmit configuration to be applied by an associated multi-channel radio frequency transmitter to produce a B₁ field in a corresponding selected region, the associated multi-channel radio frequency transmitter including a plurality of transmit elements defining at least two transmit channels, the transmit configuration selector comprising:
means for determining a B₁ field map of at least the selected region for a transmit configuration under consideration;
means for assessing the B₁ field based on at least two different quality measures; and
means for applying the B₁ mapping means and assessing means for different transmit configurations under consideration to determine the selected transmit configuration.

22. A method for determining a selected transmit configuration to be applied by a multi-channel radio frequency transmitter to produce a B₁ field in a corresponding selected region, the multi-channel radio frequency transmitter including a plurality of transmit elements defining at least two transmit channels, the method comprising:
determining a B₁ field in at least the selected region for a transmit configuration under consideration;
assessing the determined B₁ field based on at least two different quality measures; and
repeating the determining and assessing for different transmit configurations under consideration to determine the selected transmit configuration.
